(19) United States
(12) Patent Application Publication
(10) Pub. No.: US 2024/0281676 A1
(43) Pub. Date: Aug. 22, 2024

(54) METHOD FOR PREDICTING ETCHING RECIPE AND SYSTEM THEREOF

(71) Applicant: UNITED MICROELECTRONICS CORP., Hsinchu (TW)

(72) Inventors: Ming-I HO, Tainan City (TW); Tzu-Chin TSENG, Tainan City (TW); Hsin-Yu CHEN, Tainan City (TW); Ming-Wei CHEN, Tainan City (TW)

(21) Appl. No.: 18/127,018

(22) Filed: Mar. 28, 2023

(30) Foreign Application Priority Data
Feb. 16, 2023 (CN) 202310128618.5

(51) Int. Cl. G06N 5/04; G06N 5/022; H01L 21/67

(52) U.S. Cl. CPC G06N 5/04; G06N 5/022; H01L 21/67253; H01L 21/67276

(57) ABSTRACT

A method and a system for predicting etching recipe are provided, wherein the method includes steps as follows: Firstly, a plurality of etching recipes of existing etched products and a plurality sets of position-optical measurement values corresponding to the plurality of etching recipes are collected. Then, a supervised learning training is performed according to a plurality of optical measurement values in each set of the position-optical measurement values to build a predicting model. A specification data of a product to be etched including a position-optical parameter is input into this predicting model to obtain a prediction result. Subsequently, according to the prediction result, one of the plurality of etching recipes of the existing etched products is selected as a suggested etching recipe for the product to be etched.

This application claims the benefit of People's Republic of China application serial No. 202310128618.5, filed Feb. 16, 2023, the subject matter of which is incorporated herein by reference.

### BACKGROUND

### Technical Field

The disclosure relates in generally to a method and system for predicting parameters of a semiconductor manufacturing process, and in particular to a method and system for predicting etching recipe.

### Description of the Related Art

Since an etching operation plays a very important role in a semiconductor manufacturing process, thus the success or failure of the etching operation indirectly affects the yield and manufacturing cost of the semiconductor manufacturing process. Therefore, it is necessary to strictly control all the parameters in the etching operations to secure the robustness and the repeatability among each batch of the semiconductor manufacturing process. For example, in order to avoid the etching operations from under-etching or over-etching that may lead to reduce in the yield of the manufacturing process, it is necessary to accurately determine the etching endpoint, at which the providing of the etchant is stopping, and the maintenance time for keeping the etchant to continue to function.

Under normal circumstances, since the etching operations using the same etching recipe produces roughly the same etching pattern, thus an etching end point curve can be obtained by analyzing the reaction time of the reactants (for etching the target material layer) in the reaction chamber and the changes in various physical measurement values during the etching process, used to determine the etching endpoint and the maintenance time of the etchant.

However, several actual etching tests is required by using the etching end point detection (EPD) technology of prior art to obtain the etching endpoint curve. When the etching recipe altered, such as changing new circuit patterns or materials or changing different etching machines, further actual etching tests are required to obtain the etching endpoint, the maintenance time and other operation parameters for manufacturing the new semiconductor product. This results in a substantial increase in the operating steps and testing costs of the etching operation.

Therefore, there is a need of providing an improved method and system for predicting etching recipe to obviate the drawbacks encountered from the prior art.

### SUMMARY

One aspect of the present disclosure is to provide a method for predicting etching recipe, wherein the method includes steps as follows: Firstly, a plurality of etching recipes of existed etching products and a plurality sets of position-optical measurement values corresponding to the plurality of etching recipes are collected. Then, a supervised learning training is performed according to a plurality of optical measurement values in each set of the position-optical measurement values to build a predicting model. A specification data of a product to be etched including a position-optical parameter is input into this predicting model to obtain a prediction result. Subsequently, according to the prediction result, one of the plurality of etching recipes of the existing etched products is selected as a suggested etching recipe for the product to be etched.

Another aspect of the present disclosure is to provide a system for predicting etching recipe, wherein the system includes a database and a processor. The database is used to store historical data. The historical data includes a plurality of etching recipes for a plurality of existing etched products and a plurality of sets of position-optical measurement values corresponding to the plurality of the etching recipes. The processor has a predicting model built by a supervised learning training using a plurality of optical measurement values in each set of the position-optical measurement values. The predicting model is used to obtain a prediction result by inputting a specification data of a product to be etched including a position-optical parameter into this predicting model, and to select one of the plurality of the etching recipes as a suggested etching recipe for the product to be etched according to the prediction result.

In accordance with the aforementioned embodiments of the present disclosure, a method and a system for predicting an etching recipe are provided. First, a plurality of etching recipes of a plurality of existing etched products and a plurality sets of position-optical measurement values corresponding to the plurality of etching recipes are collected and stored as historical data. A predicting model is built by a supervised learning training according to a plurality of optical measurement values in each set of the position-optical measurement values. Subsequently, a specification data of a product to be etched including a position-optical parameter into this predicting model to obtain a prediction result, and one of plurality of the etching recipes is selected as a suggested etching recipe for the product to be etched according to the prediction result. As a result, the actual etching tests required by the EPD technology of prior art to obtain the etching endpoint can be omitted, and the operating steps and testing costs of the etching operation can be greatly reduced.

### BRIEF DESCRIPTION OF THE DRAWINGS

The above objects and advantages of the present disclosure will become more readily apparent to those ordinarily skilled in the art after reviewing the following detailed description and accompanying drawings, in which:

FIG. 1 is a block diagram of a system for predicting etching recipe in accordance with one embodiment of the present disclosure;

FIG. 2 is a flow chart illustrating the method for predicting etching recipe using the system for predicting etching recipe;

FIGS. 3A to 3B are cross-sectional views illustrating the partial processing structure of an etching operation performed on a conventional embedded memory device to remove a part of the dielectric material layer;

FIG. 3C is a diagram illustrating the etching endpoint curves for determining the etching endpoint in the etching operations as depicted in FIGS. 3A to 3B; and

FIG. 4 illustrates 5 equalization histograms generated from the optical measurement values that are measured in 5 different etching operations for forming different existing semiconductor devices.

### DETAILED DESCRIPTION

The embodiments as illustrated below provide a method and a system for predicting etching recipe, which can reduce the operating steps and testing costs of an etching operation. The present disclosure will now be described more specifically with reference to the following embodiments illustrating the structure and arrangements thereof.

It is to be noted that the following descriptions of preferred embodiments of this disclosure are presented herein for purpose of illustration and description only. It is not intended to be exhaustive or to be limited to the precise form disclosed. Also, it is also important to point out that there may be other features, elements, steps and parameters for implementing the embodiments of the present disclosure which are not specifically illustrated. Thus, the specification and the drawings are to be regard as an illustrative sense rather than a restrictive sense. Various modifications and similar arrangements may be provided by the persons skilled in the art within the spirit and scope of the present disclosure. In addition, the illustrations may not be necessarily drawn to scale, and the identical elements of the embodiments are designated with the same reference numerals.

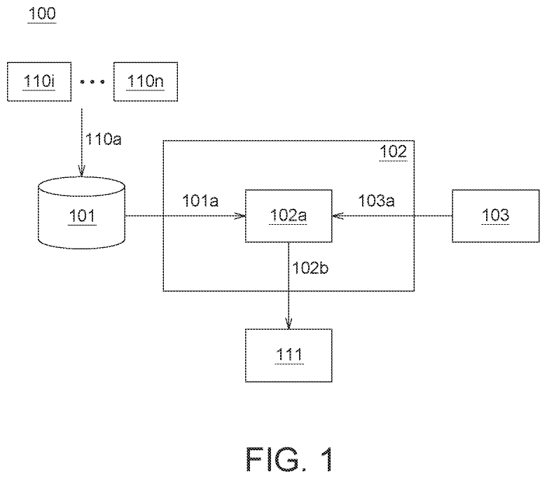

FIG. 1 is a block diagram of a system 100 for predicting etching recipe in accordance with one embodiment of the present disclosure. In some embodiments of the present disclosure, the system 100 includes a database 101 and a processor 102. The database 101 is used to store historical data 101a. The historical data 101a includes a plurality of etching recipes for a plurality of existing etched products and a plurality of sets of position-optical measurement values corresponding to the plurality of the etching recipes.

The processor 102 has a predicting model 102a built by a supervised learning training using a plurality of optical measurement values in each set of the position-optical measurement values. The predicting model 102a is used to obtain a prediction result 102b by inputting a specification data of a product 103 to be etched including a position-optical parameter into this predicting model 102a, and to select one of plurality of the etching recipes as a suggested etching recipe for performing an actual operation 111 of the product 103 to be etched according to the prediction result 102b.

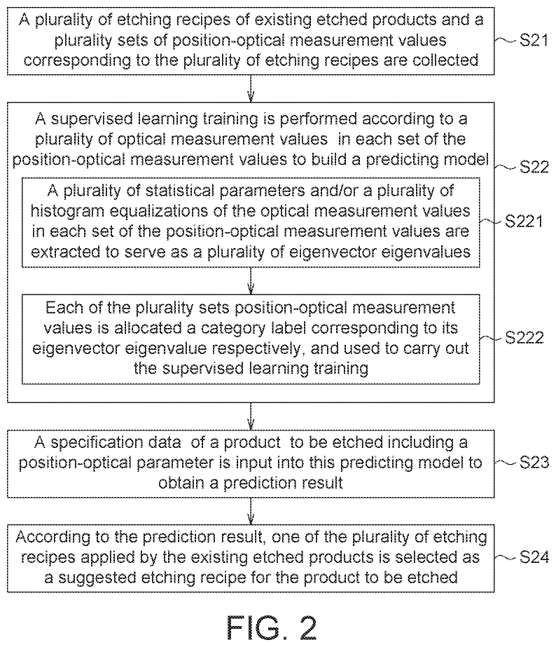

FIG. 2 is a flow chart illustrating the method for predicting etching recipe using the system 100 for predicting etching recipe. Wherein the method includes steps as follows: Firstly, (see the step S21) a plurality of etching recipes of existing etched products and a plurality sets of position-optical measurement values corresponding to the plurality of etching recipes are collected. In some embodiments of the present disclosure, the plurality of existing etched products 110p-110n (wherein, p and n are positive integers greater than 0, respectively) may be various semiconductor devices with mature manufacturing processes in the prior art. The etching recipes 110a of the existing etched products 110p-110n described here, refers to a certain set of parameters used for forming a patterned material layer (e.g., a patterned metal layer) on a surface of a certain substrate (e.g., a polysilicon layer or a dielectric layer) in a certain etching operation performed during the process of making these semiconductor devices.

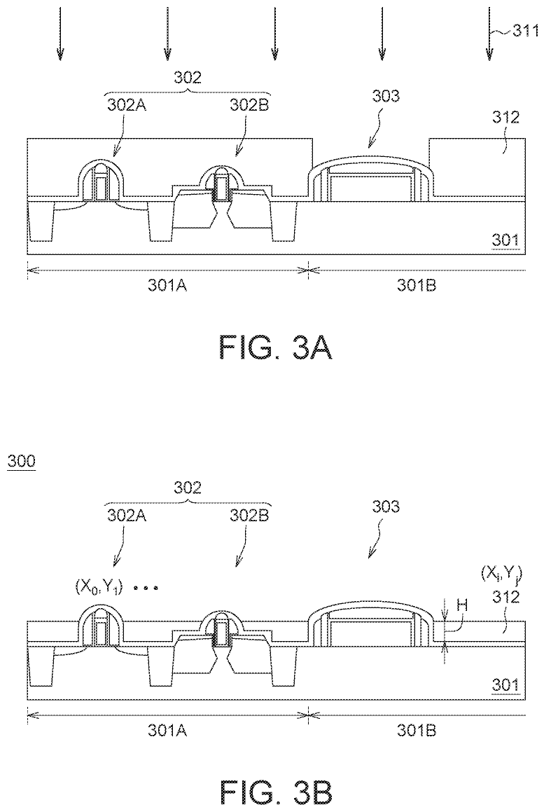

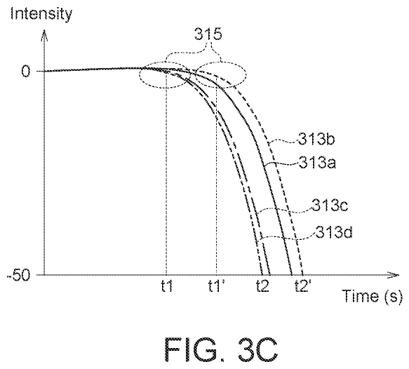

FIGS. 3A to 3B are cross-sectional views illustrating the partial processing structure of an etching operation 311 performed on a conventional embedded memory device 300 to remove a part of the dielectric material layer 312. In the present embodiment, the embedded memory device 300 at least includes a polysilicon substrate (for example, a silicon wafer) 301, a set of complementary metal-oxide-semiconductor (CMOS) transistors 302 (including a P-type metal-oxide-semiconductor (NMOS) transistor 302A and an N-type metal-oxide-semiconductor (PMOS) transistor 302B) disposed in a logic area 301A, and a memory cell 303 disposed in the memory area 301B.

Wherein, the dielectric material layer 312 may be a (developed) patterned photoresist layer, the etching step 311 is used to remove a part of the patterned photoresist layer by plasma bombardment, and to determine the endpoints 315 of different samples through the EPD technology by performing a plurality of actual etching operations on the different samples to obtain different etching endpoint curves 313a-313d (as shown in FIG. 3C), which can be used to control the remaining thickness H of the patterned photoresist layer, from which the tops of the CMOS transistors 302 (e.g. the tops of the NMOS 302A and the PMOS 302B) may be exposed.

In the present embodiment, the horizontal axis of the etching endpoint curves 313a-313d is the reaction time, and the vertical axis is the light scattering value of plasma excitation. The etching recipes 110a described here used in the etching operation 311 include (but not limited to) the etchant formula used to remove a part of the dielectric material layer 312, the reaction gas, the gas flow rate, the reaction time, the reaction temperature, the etching endpoint 315 (i.e., the time points t1 and t1′, as shown in FIG. 3C), etchant maintenance time (i.e., the time intervals t1-t2 and t1′-t2′, as shown in FIG. 3C), or any combination of the above parameters.

In addition, the plurality sets of position-optical measurement values described therein refer to a plurality of optical measurement values measured at each of a plurality of position coordinates (X₀, Y₀)-(Xᵢ, Yⱼ), after the etching operation 311 is performed on the polysilicon substrate (e.g., the silicon wafer) 301, and/or the statistical data of the optical measurement values. For example, in the present embodiment, the surface of the polysilicon substrate (e.g., the silicon wafer) 301 can be divided into a two-dimensional coordinate system of X₀-Xᵢ/Y₀-Yⱼ, and a plurality of optical measurements are respectively performed at each of the position coordinates (X0, Y0)-(Xi, Yj) of the polysilicon substrate 301 to obtain a plurality of optical measurement values, such as (but not limited to) light transmittance, reflectivity, scattering degree, etc. corresponding to each of the position coordinates and/or the statistical data of these optical measurement values. Table 1 lists a plurality of light transmittance measured at each of the position coordinates (e.g., (X₀, Y₀)-(Xᵢ, Yⱼ)) of the polysilicon substrate 301.

TABLE 1

| X | Y | Light Transmittance (%) |
|---|---|---|
| 0 | 0 | 69.5 |
| 1 | 1 | 76 |
| 2 | 2 | 75.5 |
| 3 | 3 | 96 |
| . | . | . |
| . | . | . |
| . | . | . |
| i-1 | j-1 | 70.3 |
| i | j | 67.4 |

Table 2 lists the statistical data corresponding to the light transmittance listed in Table 1, such as including (but not limited to) the mean, minimum, maximum, median, standard deviation, skewness coefficient, kurtosis coefficient, mode, coefficient of variation, 25th percentile, 75th percentile and k-s statistics etc.

TABLE 2

| Statistical data | Values |
|---|---|
| Mean | 54.48 |
| Minimum | 0 |
| Maximum | 100 |
| Median | 52 |
| Standard deviation | 8.53 |
| Skewness coefficient | 0.65 |
| Kurtosis coefficient | 12 |
| mode | 51.8 |
| Coefficient of variation | 15.7 |
| 25th percentile | 51.7 |
| 75th percentile | 56.5 |
| k-s statistics | 0.996 |

Then, (see the step S22) a supervised learning training is performed according to a plurality of optical measurement values (and/or the statistical data of the optical measurement values) (expressed as, a plurality of equalized histograms) in each set of the position-optical measurement values to build a predicting model (such as, the predicting model 102a shown in FIG. 1). In some embodiments of the present disclosure, building the predicting model includes several sub-steps as follows: Firstly, as described in sub-step S221: a plurality of statistical parameters and/or a plurality of histogram equalization parameters of the optical measurement values in each set of the position-optical measurement values are extracted to serve as a plurality of eigenvector eigenvalues.

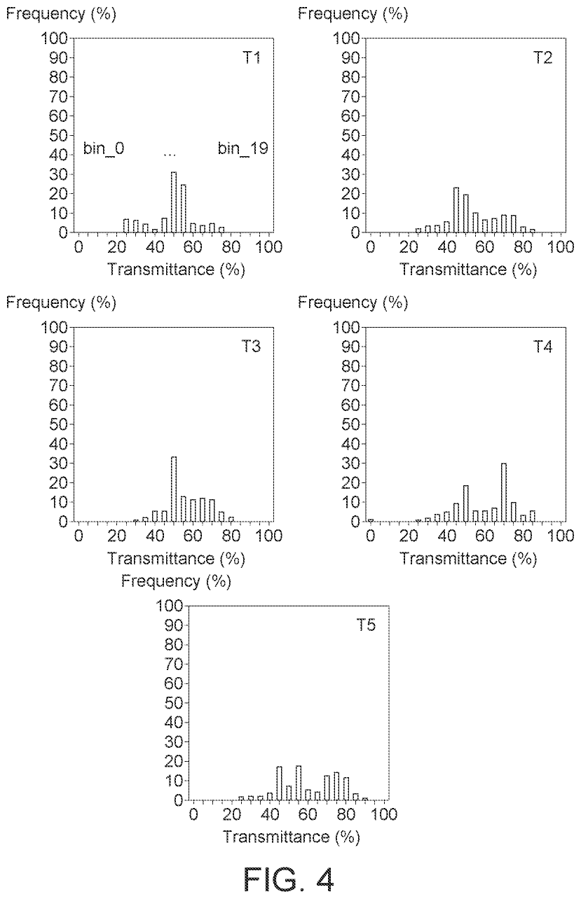

In some embodiments of the present disclosure, the light transmittance listed in Table 1 can be converted into histogram equalization parameters expressed in scalar quantities by means of normalization. For example, in the present embodiment, the light transmittance can be divided into 20 segments from the maximum value of 0 to 100 by normalization, and the frequency of occurrence falling into different transmittance segments calculation segments can be calculated, and the original measured value of the transmittance can be converted to 20 Histogram equalization parameters bin_0 to bin_19 ranging from 0 to 1, and histogram equalization parameters bin_0 to bin_19 can be drawn into a histogram (such as the histogram T1 shown in FIG. 4).

In the prior art, different equalization histograms can be generated from the optical measurement values (e.g., light transmittance) measured in different etching operations for manufacturing different or the same semiconductor devices. For example, FIG. 4 illustrates 5 equalization histograms T1-T5 generated from the optical measurement values (e.g., light transmittance) measured in 5 different etching operations for forming different existing semiconductor devices. It should be appreciated that although FIG. 4 only shows five equalization histograms T1-T5, but the optical measurement values is not limited thereto. In the existing semiconductor manufacturing process technology, any equalization histogram generated from the optical measurement value (e.g., light transmittance) etching operation measured after the etching operation do not exceed the spirit of the optical measurement values described in the disclosure.

In the present embodiment, the mean, minimum, maximum, median, standard deviation, skewness coefficient, kurtosis coefficient, mode, coefficient of variation, 25th percentile, 75th percentile and k-s statistics of the light transmittance listed in Table 2 as well as the 20 histogram equalization parameters bin_0 to bin_19 in the equalization histogram T1 (that is, the frequency values of the 20 transmittance segments), are arranged to form an eigenvector containing 32 eigenvalues (shown in Table 3).

TABLE 3

| | | | | | standard | skewness | kurtosis | | coefficient | 25th | 75th | k-s |
|---|---|---|---|---|---|---|---|---|---|---|---|---|
| | Mean | nimum | maximum | median | deviation | coefficient | coefficient | mode | of variation | percentile | percentile | statistics |
| Eigenvalues | 1 | 2 | 3 | 4 | 5 | 6 | 7 | 8 | 9 | 10 | 11 | 12 |
| Value | 54.48 | 0 | 100 | 52 | 8.53 | 0.65 | 12 | 51.8 | 15.7 | 51.7 | 56.5 | 0.996 |
| Eigenvalues | 13 | 14 | 15 | 16 | 17 | 18 | 19 | 20 | 21 | 22 | 23 | 24 |
| | bin_0 | bin_1 | bin_2 | bin_3 | bin_4 | bin_5 | bin_6 | bin_7 | bin_8 | bin_9 | bin_10 | bin_11 |
| Value | 0.4 | 0.0 | 0.0 | 0.0 | 0.0 | 0.0 | 0.3 | 0.9 | 1.2 | 7.9 | 58.0 | 18.2 |
| Eigenvalues | 25 | 26 | 27 | 28 | 29 | 30 | 31 | 32 | — | — | — | — |
| | bin_12 | bin_13 | bin_14 | bin_15 | bin_16 | bin_17 | bin_18 | bin_19 | — | — | — | — |
| Value | 5.1 | 2.6 | 1.9 | 1.5 | 0.8 | 0.5 | 0.2 | 0.5 | — | — | — | — |

Then, as described in sub-step S222: each of the plurality sets position-optical measurement values is allocated a category label corresponding to its eigenvector eigenvalue (as shown in Table 3) respectively, and used to carry out the supervised learning training. In some embodiments of the present disclosure, the supervised learning training for building the predicting model 102a may include K-nearest neighbor algorithm (KNN). In the present embodiment, 70 pieces of historical data 101a in the database 101 are selected to build the predicting model 102a using a central tendency algorithm, a discrete tendency algorithm or the combination thereof, and 30 pieces of historical data 101a in the database 101 are selected for verification to improve the predicting model 102a.

Next, as described in step S23: a specification data 103a of a product 103 to be etched including a position-optical parameter is input into this predicting model 102a to obtain a prediction result. In some embodiments of the present disclosure, the circuit pattern (not shown) to be formed by the actual etching step 111 performed on the product 103 to be etched can be simulated to obtain the preset specification data 103a including the position-optical parameter of the product 103 to be etched. For example, in the present embodiment, the preset specification data 103a of the product 103 to be etched including the position-optical parameter can be obtained by analyzing or simulating the etching mask pattern (e.g., photoresist pattern) of the actual etching operation 111.

In addition, before inputting the preset specification data 103a of the product 103 to be etched including the position-optical parameter into the predicting model 102a, a plurality of statistical parameters and/or a plurality of histogram equalization parameters of the optical measurement values of the position-optical parameter includes in the preset specification data 103a are extracted by the method described in sub-step S221 to serve as a plurality of eigenvector eigenvalues of the preset specification data 103a. Afterwards, the eigenvector eigenvalues of the preset specification data 103a of the product 103 to be etched can be input into the prediction model 102a, and then compared and analyzed with the eigenvector eigenvalues of each set of the position-optical measurement values collected from different etching operations of the existing etched products and stored in the historical data 101a. Finally, a probability value of each set of the position-optical measurement values of different etching operations (i.e., the prediction result 102b).

Subsequently, as described in step S24: according to the prediction result 102b, one of the plurality of etching recipes applied by the existing etched products is selected as a suggested etching recipe for the product 103 to be etched. In some embodiments of the present disclosure, the equalization histograms (for example, the histogram equalization parameters shown in the equalization histogram T2) and the existing etching parameters corresponding to the highest one (at least greater than 90%) of the plurality probability values output by the prediction model 102a can be selected as the suggested etching recipe of the actual etching operation 111 to be performed subsequently on the product 103 to be etched. Since the actual etching tests required by the EPD technology of prior art to obtain the etching endpoint can be omitted, thus the operating steps and testing costs of the etching operation performed on the product 103 to be etched can be greatly reduced.

In accordance with the aforementioned embodiments of the present disclosure, a method and a system for predicting an etching recipe are provided. First, a plurality of etching recipes of a plurality of existing etched products and a plurality sets of position-optical measurement values corresponding to the plurality of etching recipes are collected and stored as historical data. A predicting model is built by a supervised learning training according to a plurality of optical measurement values in each set of the position-optical measurement values. Subsequently, a specification data of a product to be etched including a position-optical parameter into this predicting model to obtain a prediction result, and one of plurality of the etching recipes is selected as a suggested etching recipe for the product to be etched according to the prediction result. As a result, the actual etching tests required by the EPD technology of prior art to obtain the etching endpoint can be omitted, and the operating steps and testing costs of the etching operation can be greatly reduced.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for predicting etching recipe, comprising:
collecting a plurality of etching recipes of a plurality of existed etching products and a plurality sets of position-optical measurement values corresponding to the plurality of etching recipes;
performing a supervised learning training according to a plurality of optical measurement values in each of the plurality sets of position-optical measurement values to build a predicting model;
inputting a specification data of a product to be etched including a position-optical parameter into the predicting model to obtain a prediction result; and
selecting one of the plurality of etching recipes, according to the prediction result, as a suggested etching recipe for the product to be etched.

2. The method according to claim 1, wherein building the predicting model comprises:
extracting a plurality of statistical parameters and/or a plurality of histogram equalization parameters of a plurality of optical measurement values in each of the plurality sets of position-optical measurement values to serve as a plurality of eigenvector eigenvalues; and
allocating each of the plurality of position-optical measurement values a category label corresponding to the plurality of eigenvector eigenvalues respectively, for carrying out the supervised learning training.

3. The method according to claim 2, wherein the supervised learning training for building the predicting model comprises a K-nearest neighbor algorithm (KNN).

4. The method according to claim 2, wherein the plurality of position-optical measurement values comprise a plurality of position coordinates-light transmittance values of the plurality of existed etching products.

5. The method according to claim 2, wherein the plurality of statistical parameters comprises a mean, a minimum, a maximum, a median, a standard deviation, a skewness coefficient, a kurtosis coefficient, a mode, a coefficient of variation, a 25th percentile, a 75th percentile and a k-s statistics of the plurality of position-optical measurement values.

6. The method according to claim 2, wherein the plurality of histogram equalization parameters are plurality of probability values obtained by normalizing each of the plurality of position-optical measurement values.

7. A system for predicting etching recipe, comprising:
a database, used to store a historical data comprising a plurality of etching recipes for a plurality of existing etched products and a plurality of sets of position-optical measurement values corresponding to the plurality of the etching recipes; and
a processor, comprising a predicting model built by a supervised learning training using a plurality of optical measurement values in each of the plurality of sets of position-optical measurement values;
wherein the predicting model is used to obtain a prediction result by inputting a specification data of a product to be etched including a position-optical parameter into the predicting model, and to select one of the plurality of the etching recipes as a suggested etching recipe for the product to be etched according to the prediction result.

8. The system according to claim 7, wherein building the predicting model comprises:
extracting a plurality of statistical parameters and/or a plurality of histogram equalization parameters of a plurality of optical measurement values in each of the plurality sets of position-optical measurement values to serve as a plurality of eigenvector eigenvalues; and
allocating each of the plurality of position-optical measurement values a category label corresponding to the plurality of eigenvector eigenvalues respectively, for carrying out the supervised learning training.

9. The system according to claim 8, wherein the supervised learning training for building the predicting model comprises a K-nearest neighbor algorithm (KNN).

10. The system according to claim 8, wherein the plurality of position-optical measurement values comprise a plurality of position coordinates-light transmittance values of the plurality of existed etching products.

11. The system according to claim 8, wherein the plurality of statistical parameters comprises a mean, a minimum, a maximum, a median, a standard deviation, a skewness coefficient, a kurtosis coefficient, a mode, a coefficient of variation, a 25th percentile, a 75th percentile and a k-s statistics of the plurality of position-optical measurement values.

12. The system according to claim 8, wherein the plurality of histogram equalization parameters are plurality of probability values obtained by normalizing each of the plurality of position-optical measurement values.
